(19) United States
(12) Patent Application Publication
(10) Pub. No.: US 2025/0389793 A1
(43) Pub. Date: Dec. 25, 2025

(54) METHOD AND SYSTEM FOR CALCULATING MAIN-LOOP PARAMETERS OF SLCC, AND READABLE MEDIUM

(71) Applicant: STATE GRID ECONOMIC AND TECHNOLOGICAL RESEARCH INSTITUTE CO., LTD, Beijing (CN)

(72) Inventors: Weimin MA, Beijing (CN); Ling WANG, Beijing (CN); Ming LI, Beijing (CN); Fangjie WU, Beijing (CN); Xiaolin SHEN, Beijing (CN); Ying XU, Beijing (CN); Yinglin XUE, Beijing (CN); Tao ZHANG, Beijing (CN); Yiming JI, Beijing (CN); Shangan DU, Beijing (CN); Zhiyuan HAO, Beijing (CN); Shaowei WANG, Beijing (CN); Ao WANG, Beijing (CN); Tierui ZOU, Beijing (CN); Zijian GAO, Beijing (CN); Tianxiang LEI, Beijing (CN)

(21) Appl. No.: 18/880,302

(22) PCT Filed: Aug. 10, 2023
(86) PCT No.: PCT/CN2023/112350

§ 371 Date: Dec. 31, 2024

(30) Foreign Application Priority Data
Aug. 17, 2022 (CN) 202210984714.5

(51) Int. Cl. G01R 31/56; G01R 19/25

(52) U.S. Cl. CPC G01R 31/56; G01R 19/25

(57) ABSTRACT

A method and system for calculating main-loop parameters of an SLCC, and a readable medium. The method comprises the following steps: according to an equivalent circuit model and a simplified equivalent circuit model, calculating an ideal no-load rated direct-current voltage by means of a Newton-Raphson iteration method (S10); according to the ideal no-load rated direct-current voltage and in combination with an alternating-current system reactive power control target and a direct-current system angle control target, calculating main-loop parameters in the equivalent circuit model and the simplified equivalent circuit model (S20); and determining whether calculation results of the main-loop parameters are within a preset range, and if the calculation results of the main-loop parameters are within the preset range, outputting the calculation results, and if the calculation results of the main-loop parameters are not within the preset range, after the parameters are modified, performing the above steps again until the calculation results of all parameters are within the preset range (S30).

### CROSS-REFERENCE TO RELATED APPLICATION

This application is a national stage of International Application No. PCT/CN2023/112350, filed on Aug. 10, 2023, which is based on and claims the priority of a Chinese patent application No. 202210984714.5, filed on Aug. 17, 2022, and entitled “METHOD AND SYSTEM FOR CALCULATING MAIN-LOOP PARAMETERS OF SLCC, AND READABLE MEDIUM”, the disclosure of which is incorporated by reference herein in its entirety.

### TECHNICAL FIELD

The disclosure relates to the technical field of transmission system, particularly to a method and system for calculating main circuit parameters of a Statcom and Line Commutation Converter (SLCC), and a readable medium.

### BACKGROUND

Line commutated converter (LCC) direct current transmission technology is the most widely used form of direct-current transmission technology in the State Grid at present, and plays an irreplaceable role in the field of long-distance and large-capacity power transmission. However, the LCC direct-current transmission technology, which uses thyristor as commutating device, still has the following essential defects: (1) it depends on a commutating voltage and is difficult to operate stably in weak systems; (2) it requires a large commutating angle, a large amount of reactive power is consumed, and a large amount of reactive power compensation device is required; (3) a switching speed of a circuit breaker of the reactive power device is slow, and when a fault occurs, the circuit breaker of the reactive power device cannot cooperate with firing angle control of the thyristor of the direct-current system for flexible cooperation, resulting in excess reactive power and overvoltage in an alternating-current system; (4) there is a risk of commutation failure. For the current grid structure where direct-currents of multiple circuits are collected and fed into a same alternating-current power grid, the direct-current lines are coupled with each other, which may lead to commutation failure of multiple direct-currents, thereby expanding the accident.

The voltage source converter (VSC) technology, that is, flexible direct-current transmission technology, uses a voltage source converter composed of fully-controlled power electronic devices. Therefore, the VSC can not only independently control the output of active power and the output of reactive power, but also supply power to weak systems or even passive systems. There is no need to configure a reactive power compensation device, the output voltage has small harmonics, and inter-station communication is not required. Compared with conventional direct-current transmission, the footprint of the converter station and electromagnetic pollution are also greatly reduced.

The SLCC technology is a newly proposed commutation technology with the characteristics of both voltage source and current source. The topological structure of the SLCC is illustrated in FIG. 1, which can realize optimization and upgrade of the performances of the LCC and the VSC. Specifically, the optimization and upgrade of the performances are as follows. (1) By utilizing the voltage source characteristics, dependence on the alternating-current system is reduced, dynamic reactive power characteristics are improved, renewable energy islanding feed-in is flexibly adapted, the risk of commutation failure is reduced, and at the same time, harmonic pollution in alternating-current power grid is effectively avoided, equipment stress is significantly reduced and the reliability of safe equipment operation is improved. (2) The mature high-capacity power electronic devices are adopted, which offers a high reliability, a low loss, and with no limitations on capacity scale. (3) By coordinating control of the voltage source and the current source, the risk of oscillations caused by single voltage source converters is effectively reduced. (4) The configuration for the alternating-current filter is removed, which greatly reduces the total footprint of the converter stations.

In the development of new power systems, common issues include a high randomness and volatility of wind power generation and photovoltaic power generation, small system inertia, and the difficulty for the renewable energy in providing reactive power support to the system. Therefore, the traditional direct-current transmission systems face severe challenges. SLCC, as a new direct-current commutation technology, has a higher adaptability and will lead direct-current technology to achieve new upgrades.

As a new technology, the topological structure mentioned above combines the characteristics of fully-controlled devices and semi-controlled devices, which makes it more complex and difficult in terms of control strategies and simulation model building compared to previous direct-current transmission technologies (such as LCC and VSC). However, all foundations are first solving for comprehensive system parameters. In the conventional method for calculating the main circuit parameters of the LCC, due to the lack of mutual coupling between variables, parameters such as an ideal controlled direct-current voltage Udi0, a commutating angle and reactive power consumption of the converter are typically solved based on a direct-current voltage and a direct-current target current. The calculation of the main circuit parameters of the SLCC technology involves two branches, parameters (such as a valve-side voltage, a valve-side current, a branch current of static var compensator (SVG), a branch voltage of the SVG, a reactive power output of the SVG) are deeply coupled with each other, which makes it very difficult to solve the calculations. However, the solution of the main circuit parameters is very critical, which directly affects the selection of parameters of a converter transformer and the subsequent calculations of other primary equipment.

### SUMMARY

In response to the above issues, the purpose of the disclosure is to provide a method and system for calculating main circuit parameters of an SLCC, and a readable medium, which can quickly and accurately calculate parameters such as a direct-current voltage and a direct-current current, an active power and a reactive power, a tap-changer position and a reactive power output of the SVG for each of the power points at the transmitting terminal and the receiving terminal, thereby providing reliable data for the selection of key equipment in the direct-current system.

In order to achieve the above objectives, the disclosure provides a technical solution, that is, a method for calculating main circuit parameters of an SLCC, which includes the following operations. An ideal no-load rated direct-current voltage is calculated through a Newton-Raphson iteration method based on an equivalent circuit model and a simplified equivalent circuit model. A main circuit parameter in the equivalent circuit model and a main circuit parameter in the simplified equivalent circuit model are calculated based on the ideal no-load rated direct-current voltage in combination with a reactive power control target for an alternating-current system and an angle control target for a direct-current system. Whether calculation results of the main circuit parameters are within a preset range is determined. In case that the calculation results of the main circuit parameters are within the preset range, the calculation results are outputted. In case that the calculation results of the main circuit parameters are not within the preset range, the parameters are modified and the previous operations are re-performed until the calculation results of all of the parameters are within the preset range.

In some embodiments, the equivalent circuit model includes a main circuit and an SVG branch. The main circuit includes a first alternating-current signal source and an equivalent impedance of a converter transformer. The first alternating-current signal source is connected in series with the equivalent impedance of the converter transformer, and an output terminal of the equivalent impedance of the converter transformer is connected to a converter valve of an LCC. The SVG branch includes a second alternating-current signal source and an inductance of a connecting reactor. The second alternating-current signal source is connected in series with the inductance of the connecting reactor, and an output terminal of the inductance of the connecting reactor is connected to the main circuit.

In some embodiments, the simplified equivalent circuit model includes a third alternating-current signal source and a synthetic equivalent impedance of a combined impedance of the converter transformer and the SVG. The third alternating-current signal source is connected in series with the synthetic equivalent impedance of the combined impedance of the converter transformer and the SVG, and an output terminal of the synthetic equivalent impedance of the combined impedance of the converter transformer and the SVG is connected to the converter valve of the LCC.

In some embodiments, the operation of calculating the ideal no-load rated direct-current voltage includes the following operations. The main circuit parameter in the simplified equivalent circuit model is calculated based on an initial value of a voltage parameter at a grid connection point. The main circuit parameter in the equivalent circuit model is calculated based on the initial value of the voltage parameter at the grid connection point. A parameter of the SVG branch of the equivalent circuit model is calculated based on the initial value of the voltage parameter at the grid connection point. The ideal no-load rated direct-current voltage is iteratively solved based on the main circuit parameter in the simplified equivalent circuit model, the main circuit parameter in the equivalent circuit model and the parameter of the SVG branch of the equivalent circuit model.

In some embodiments, the main circuit parameter in the simplified equivalent circuit model includes: a commutating angle, a reactive power consumption, and a transmission current. The main circuit parameter in the equivalent circuit model includes: a reactive power consumption of the converter transformer, a grid-side current and a power factor. The parameter of the SVG branch of the equivalent circuit model includes: a reactive power output of the SVG, a reactive power consumption of the connecting reactor, a reactive power consumption when disconnected and a voltage of a voltage source in the SVG.

In some embodiments, the operation of calculating the main circuit parameter in the equivalent circuit model and the main circuit parameter in the simplified equivalent circuit model includes the following operations. A power step size under multiple operating conditions and multiple powers and an actual reactive power exchange control value for each of power points are set. Operating characteristics of the direct-current system under the multiple operating conditions with condition constraints are calculated through the Newton iteration method. The main circuit parameter in the equivalent circuit model and the main circuit parameter in the simplified equivalent circuit model are determined.

In some embodiments, under a full-voltage operating condition, a reactive power exchange control value for a direct-current power is set, and a steady-state parameter for each of the power points is calculated one by one. During calculating the steady-state parameter, the Newton-Raphson method is adopted by setting: F(x)=Qₜᵢ−3Iₜᵢ·ω·L_{apf}−Qₜ₁ᵢ, x=U_{L}. An initial value and an iteration step size are set, and if F(x1)=0, the iteration ends. Where, i indicates a N-th power point, Qₜ indicates the reactive power output of the SVG, Iₜ indicates a current of the SVG branch, L_{apf} indicates the inductance of the connecting reactor, and U_{L} indicates a voltage at a grid connection point of the SVG.

In some embodiments, under a reduced-voltage operating condition, a reduced-voltage coefficient k is set, a reactive power exchange control value of a direct-current power from 0.1 to k is set, and a steady-state parameter for each of the power points is calculated one by one. During calculating the steady-state parameters, the Newton-Raphson method is adopted by setting F(x)=Qₜᵢ−3Iₜᵢ²·ω·L_{apf}−Qₜ₁ᵢ. Where, i indicates a N-th power point, x=U_{L}. An initial value and an iteration step size are set, and if F(x1)=0, the iteration ends. Where, i indicates a N-th power point, Qₜ indicates the reactive power output of the SVG, Iₜ indicates a current of the SVG branch, L_{apf} indicates the inductance of the connecting reactor, and U_{L} indicates a voltage at a grid connection point of the SVG.

The disclosure also provides a system for calculating main circuit parameters of an SLCC, and the system includes a calculation section for a no-load rated direct-current voltage, a calculation section for the main circuit parameters and an output section. The calculation section for a no-load rated direct-current voltage is configured to calculate the ideal no-load rated direct-current voltage through a Newton-Raphson iteration method based on an equivalent circuit model and a simplified equivalent circuit model. The calculation section for the main circuit parameters is configured to calculate a main circuit parameter in the equivalent circuit model and a main circuit parameter in the simplified equivalent circuit model based on the ideal no-load rated direct-current voltage in combination with a reactive power control target for an alternating-current system and an angle control target for a direct-current system. The output section is configured to determine whether calculation results of the main circuit parameter are within a preset range. In case that the calculation results of the main circuit parameters are within the preset range, the calculation results are outputted. In case that the calculation results of the main circuit parameters are not within the preset range, the parameters are modified and the previous operations are re-performed until the calculation results of all of the parameters are within the preset range.

The disclosure also provides a computer-readable storage medium having stored thereon computer programs that when executed by a processor, implement the method for calculating the main circuit parameters of the SLCC of any one of the described above.

Due to the adoption of the above technical solutions, the disclosure has the following advantages.
1. The disclosure can quickly and accurately calculate parameters such as a direct-current voltage and a direct-current current, an active power and a reactive power, a tap-changer position and a reactive power output of the SVG for each of the power points at the transmitting terminal and the receiving terminal, thereby providing reliable data for the selection of key equipment in the direct-current system.
2. The disclosure can overcome a series of technical shortcomings of the traditional LCC direct-current transmission technology, and solve the problems of high dependence on the alternating-current system and poor adaptability in large-scale renewable energy collection scenarios, such that overvoltage at the transmitting terminal and low voltage at the receiving terminal can be effectively suppressed, and the risk of commutation failure is reduced. The disclosure can also avoid power quality pollution and oscillation caused by harmonics flowing into the alternating-current system, and equipment safety risks caused by frequent operations of an on-load tap-changer and repeated switching of a filter are significantly reduced.

### BRIEF DESCRIPTION OF THE DRAWINGS

FIG. 1 is a schematic structural diagram of a commutation converter valve of an SLCC in a related art.

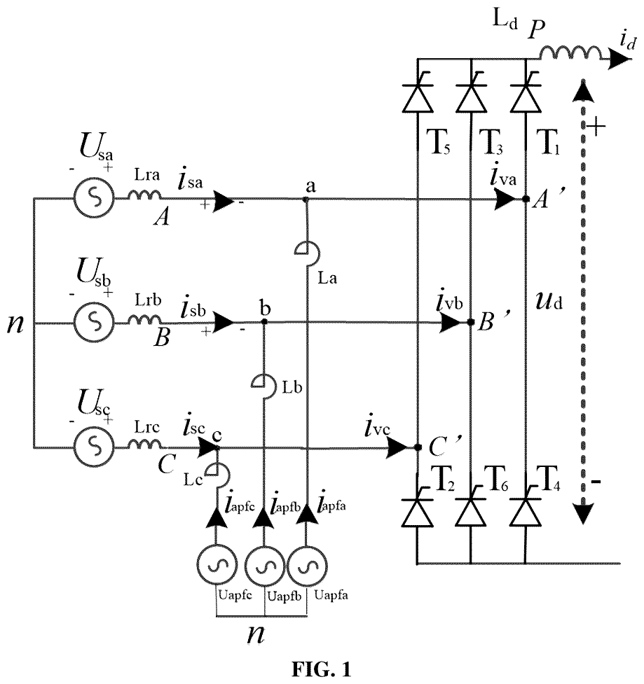

FIG. 2 is a schematic flowchart of a method for calculating main circuit parameters of an SLCC according to an embodiment of the disclosure.

FIG. 3 is a schematic structural diagram of an equivalent circuit model of a commutation converter valve of the SLCC according to an embodiment of the disclosure.

FIG. 4 is a schematic structural diagram of a simplified equivalent circuit model of a commutation converter valve of the SLCC according to another embodiment of the disclosure.

FIG. 5 is a schematic flowchart of a method for calculating an ideal no-load rated direct-current voltage according to an embodiment of the disclosure.

### DETAILED DESCRIPTION

In order to enable those of skilled in the art to better understand the technical solutions of the disclosure, the disclosure is described in detail by way of specific embodiments. However, it should be understood that the specific implementations are provided merely for a better understanding of the disclosure, and therefore cannot be understood as a limitation of the disclosure. In the description of the disclosure, it should be understood that the terms used are for descriptive purposes only and cannot be understood to indicate or imply relative importance.

For the problems of high dependence on the alternating-current system and poor adaptability in large-scale renewable energy collection scenarios of the traditional LCC direct-current transmission technology in the related art, the disclosure provides a method and system for calculating main circuit parameters of an SLCC, and a readable medium. The method includes the following operations. An ideal no-load rated direct-current voltage is calculated through a Newton-Raphson iteration method based on an equivalent circuit model and a simplified equivalent circuit model. A main circuit parameter in the equivalent circuit model and a main circuit parameter in the simplified equivalent circuit model are calculated. Whether calculation results of the main circuit parameters are within a preset range is determined. In case that the calculation results of the main circuit parameters are within the preset range, the calculation results are outputted. In case that the calculation results of the main circuit parameters are not within the preset range, the parameters are modified and the previous operations are re-performed until the calculation results of all of the parameters are within the preset range. The solutions of the disclosure can effectively suppress overvoltage at the transmitting terminal and low voltage at the receiving terminal, and reduce the risk of commutation failure; also avoid power quality pollution and oscillation caused by harmonics flowing into the alternating-current system, and equipment safety risks caused by frequent operations of an on-load tap-changer and repeated switching of a filter are significantly reduced. Hereinafter, the solutions of the disclosure will be described in detail by way of embodiments with reference to the accompanying drawings.

### First Embodiment

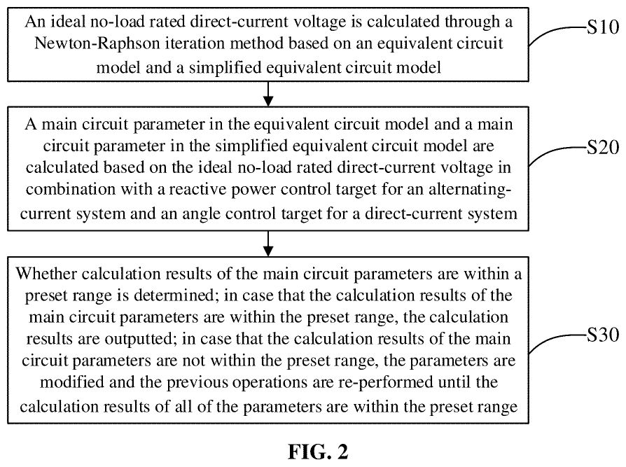

The embodiment provides a method for calculating main circuit parameters of an SLCC. FIG. 2 illustrates a schematic flowchart of the method for calculating the main circuit parameters of the SLCC, and the method includes the following operations.

In operation S10: an ideal no-load rated direct-current voltage is calculated through a Newton-Raphson iteration method based on an equivalent circuit model and a simplified equivalent circuit model.

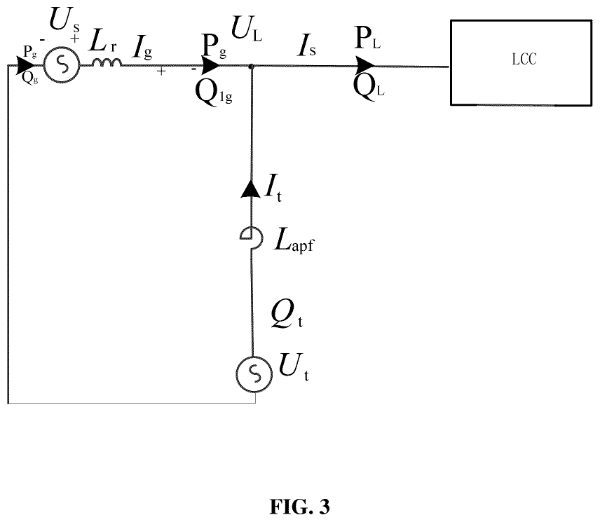

Herein, the equivalent circuit model is illustrated in FIG. 3, and a positive direction of current is defined as a flow direction from the alternating-current system to the direct-current system. The equivalent circuit model includes a main circuit and an SVG branch. The main circuit includes a first alternating-current signal source and an equivalent impedance of a converter transformer. The first alternating-current signal source is connected in series with the equivalent impedance of the converter transformer, and an output terminal of the equivalent impedance of the converter transformer is connected to a converter valve of an LCC. The SVG branch includes a second alternating-current signal source and an inductance of a connecting reactor. The second alternating-current signal source is connected in series with the inductance of the connecting reactor, and an output terminal of the inductance of the connecting reactor is connected to the main circuit. Herein, in the main circuit, Uₛ is a voltage transmitted by an alternating-current system at the transmitting terminal; I_{g} is a grid-side current; P_{g} is an active power transmitted by a valve-side of a converter transformer; Lᵣ is an equivalent impedance of the converter transformer; Q_{lg} is a reactive power transmitted by the valve-side of the converter transformer; U_{L} is a voltage at a grid connection point of the SVG; Iₛ is a valve-side current of the converter transformer; and P_{L} and Q_{L} are an active power and a reactive power flowing into the converter valve of the LCC, respectively. In the SVG branch, Iₜ is a current of the branch, L_{apf} is an inductance of a connecting reactor; Qₜ is a reactive power output of the SVG, and Uₜ is an equivalent voltage of the SVG.

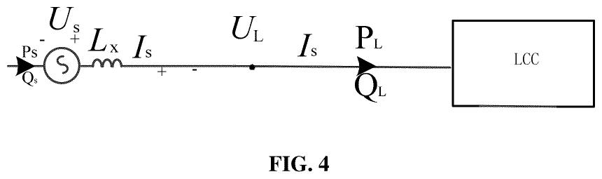

As illustrated in FIG. 4, the simplified equivalent circuit model includes a third alternating-current signal source and a synthetic equivalent impedance of a combined impedance of the converter transformer and the SVG. The third alternating-current signal source is connected in series with the synthetic equivalent impedance of the combined impedance of the converter transformer and the SVG, and an output terminal of the synthetic equivalent impedance of the combined impedance of the converter transformer and the SVG is connected to the converter valve of the LCC.

The simplified equivalent circuit model is illustrated in FIG. 4, where Uₛ, Pₛ, Qₛ are the voltage, the active power and the reactive power transmitted by the alternating-current system at the transmitting terminal, respectively; and Lx is the synthetic equivalent impedance of the combined impedance of the converter transformer and the SVG. Iₛ is the valve-side current of the converter transformer; U_{L} is the voltage at a grid connection point of the SVG; and P_{L} and Q_{L} are an active power and a reactive power flowing into the converter valve of the LCC, respectively. The same equivalent model applies to the receiving terminal. In the following, only R and I are added to indicate the transmitting terminal and the receiving terminal, respectively.

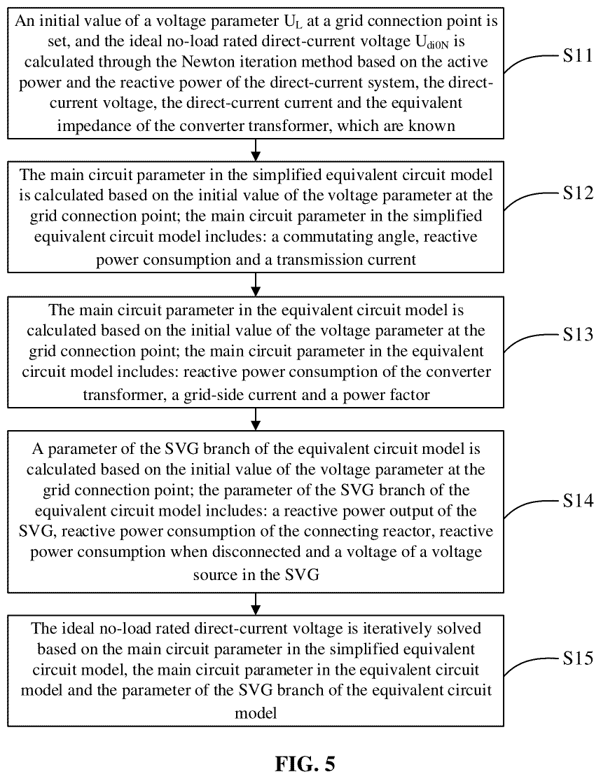

FIG. 5 illustrates a schematic flowchart of a method for calculating an ideal no-load rated direct-current voltage. The method for calculating an ideal no-load rated direct-current voltage includes operations S11 to S15.

In operation S11: an initial value of a voltage parameter U_{L} at a grid connection point is set, and the ideal no-load rated direct-current voltage U_{di0N} is calculated through the Newton iteration method based on the active power and the reactive power of the direct-current system, the direct-current voltage, the direct-current current and the equivalent impedance of the converter transformer, which are known.

In operation S12: the main circuit parameter in the simplified equivalent circuit model is calculated based on the initial value of the voltage parameter at the grid connection point. The main circuit parameter in the simplified equivalent circuit model includes: a commutating angle, reactive power consumption and a transmission current.

Herein, the calculation formula for the equivalent impedance Lx is formula (1):

$${L}_{x} = \frac{{L}_{r} {L}_{apf}}{{L}_{r} + {L}_{apf}} . \qquad formula ( 1 )$$

Herein, the calculation formula for the ideal no-load voltage U_{di02} of the direct-current system is formula (2):

$${U}_{di 02} = \frac{\frac{{U}_{d}}{2 n} + {U}_{T} + {I}_{d} {L}_{x} ω 3 / pi}{cos α} . \qquad formula ( 2 )$$

Where, n is the number of twelve-pulse converters.

Herein, the calculation formula for the commutating angle μ is formula (3):

$$μ = a cos ( cos α - 6 \; 100 {L}_{x} {I}_{d} / {U}_{di 02} ) - α . \qquad formula ( 3 )$$

Herein, the calculation formula for the overall reactive power consumption of the converter device is formula (4):

$${Q}_{L} = 2 n {I}_{d} {U}_{di 02} \cdot \frac{2 μ + sin ( 2 α ) - sin ( 2 α + 2 μ )}{4 [ cos ( α ) - cos ( α + μ ) ]} . \qquad formula ( 4 )$$

Herein, the calculation formula for the overall power factor of the converter valve device is formula (5):

$${ϕ}_{v} = A tan ( \frac{( {Q}_{s} - 3 / 2 ω {L}_{x} {I}_{s} {I}_{s} )}{{P}_{L}} ) . \qquad formula ( 5 )$$

Herein, the calculation formula for the valve-side current Iₛ of the converter is formula (6):

$${I}_{s} = {P}_{s} / \sqrt{3} / ( {U}_{di 02} π / 3 / \sqrt{2} ) / cos {ϕ}_{v} \sqrt{2} . \qquad formula ( 6 )$$

In operation S13: the main circuit parameter in the equivalent circuit model is calculated based on the initial value of the voltage parameter at the grid connection point. The main circuit parameter in the equivalent circuit model includes: reactive power consumption of the converter transformer, a grid-side current and a power factor.

Herein, the current I_{g} flowing through the converter transformer may be determined by formula (7):

$${( {P}_{S} + {Q}_{S} )}^{2} + {( {Q}_{s} - 3 / 2 {L}_{r} {I}_{g}^{2} )}^{2} = {( 3 / 2 {U}_{L} {I}_{g} )}^{2} . \qquad formula ( 7 )$$

The power factor of the converter transformer branch may be determined by formula (8):

$${θ}_{vgvi} = a tan ( {Q}_{g} / {P}_{g} ) . \qquad formula ( 8 )$$

The current phase of the converter transformer branch may be determined by formula (9):

$${θ}_{ig} = {θ}_{vg} - {θ}_{vgvi} . \qquad formula ( 9 )$$

η_{vg} is a phase angle of the valve-side voltage, and an angle of a line voltage on the grid-side with 0 degree is taken as a starting angle. Similarly, the reactive power consumption of the impedance of the converter transformer is calculated with reference to formula (10):

$${Q}_{\_ Lg} = 3 * ω * {L}_{r} * {I}_{g} * {I}_{g} / 2. \qquad formula ( 10 )$$

The reactive power passing through the impedance of the converter transformer may be determined by formula (11):

$${Q}_{Lg} = {Q}_{g} - {Q}_{\_ Lg} . \qquad formula ( 11 )$$

The power factor at the grid connection point of the converter transformer branch may be determined by formula (12):

$${θ}_{VLvi} = a tan ( \frac{{Q}_{Lg}}{{P}_{g}} ) . \qquad formula ( 12 )$$

A phase angle of the voltage at the grid connection point of the converter transformer branch may be determined by formula (13):

$${θ}_{VL} = {θ}_{VLvi} + {θ}_{ig} . \qquad formula ( 13 )$$

In operation S14: a parameter of the SVG branch of the equivalent circuit model is calculated based on the initial value of the voltage parameter at the grid connection point. The parameter of the SVG branch of the equivalent circuit model includes: a reactive power output of the SVG, a reactive power consumption of the connecting reactor, a reactive power consumption when disconnected and a voltage of a voltage source in the SVG.

Herein, the current phase of the SVG branch may be determined by formula (14):

$${θ}_{is} = {θ}_{VL} - a tan ( {Q}_{L} / {P}_{s} ) . \qquad formula ( 14 )$$

The voltage phase of the equivalent voltage source in the SVG may be determined by formula (15):

$${θ}_{vs} = {θ}_{is} + a tan ( {Q}_{s} / {P}_{s} ) . \qquad formula ( 15 )$$

The voltage magnitude of the equivalent voltage source in the SVG may be determined by formula (16):

$${U}_{t} = \sqrt{{( ( ( {L}_{apf} + {L}_{r} ) * Us * cos {θ}_{vs} - {L}_{apf} * {V}_{g} * cos {θ}_{vg} ) / {L}_{r} )}^{2} + {( ( ( {L}_{apf} + {L}_{r} ) * Us * cos {θ}_{vs} - {L}_{apf} * {V}_{g} * sin {θ}_{vg} ) / {L}_{r} )}^{2}} . \qquad formula ( 16 )$$

The current magnitude of the SVG branch may be determined by formula (17):

$${I}_{t} = \sqrt{( {( {U}_{t} * sin ( {θ}_{vt} ) - {U}_{L} * sin ( {θ}_{vL} ) / ( ω {L}_{apf} ) / \sqrt{3} \sqrt{2} )}^{2} + {( ( - {U}_{t} * cos ( {θ}_{vL} ) + {U}_{L} * cos ( {θ}_{vL} ) ) / ( ω {L}_{apf} ) / \sqrt{3} \sqrt{2} )}^{2}} . \qquad formula ( 17 )$$

The reactive power output at the outlet of the SVG branch may be determined by formula (18):

$${Q}_{t} = {Q}_{g} - ( {Q}_{Lg} - {Q}_{L} ) . \qquad formula ( 18 )$$

The reactive power output of the voltage source in the SVG may be determined by formula (19):

$${Q}_{t 1} = \sqrt{3} {V}_{t} {I}_{t} sin ( a tan ( {Q}_{t} / ( Pg - Ps ) ) ) . \qquad formula ( 19 )$$

In operation S15: the ideal no-load rated direct-current voltage is iteratively solved based on the main circuit parameter in the simplified equivalent circuit model, the main circuit parameter in the equivalent circuit model and the parameter of the SVG branch of the equivalent circuit model.

In operation S20: a main circuit parameter in the equivalent circuit model and a main circuit parameter in the simplified equivalent circuit model are calculated based on the ideal no-load rated direct-current voltage in combination with a reactive power control target for an alternating-current system and an angle control target for a direct-current system.

The operation of calculating the main circuit parameter in the equivalent circuit model and the main circuit parameter in the simplified equivalent circuit model includes the following operations. A power step size under multiple operating conditions and multiple powers and an actual reactive power exchange control value for each of power points are set. Operating characteristics of the direct-current system under the multiple operating conditions with condition constraints are calculated through the Newton iteration method. The main circuit parameter in the equivalent circuit model and the main circuit parameter in the simplified equivalent circuit model are determined.

Under a full-voltage operating condition, a reactive power exchange control value for a direct-current power from 0.1 pu to 1.0 pu is set, and a steady-state parameter for each of the power points is calculated one by one. During calculating the steady-state parameter, the Newton-Raphson method is adopted by setting: F(x)=Qₜᵢ−3Iₜᵢ²·ω·L_{apf}−Qₜ₁ᵢ, x=U_{L}. An initial value and an iteration step size are set, and if F(x1)=0, the iteration ends and parameters of the operating characteristics are returned. Where, i indicates a N-th power point, Qₜ indicates the reactive power output of the SVG, Iₜ indicates a current of the SVG branch, L_{apf} indicates the inductance of the connecting reactor, and U_{L} indicates a voltage at a grid connection point of the SVG.

Under a reduced-voltage operating condition, a reduced-voltage coefficient k=0.7, 0.8, 0.9, etc. in a range of [0.5, 1.0] is set, a reactive power exchange control value of a direct-current power from 0.1 to k is set, and a steady-state parameter for each of the power points is calculated one by one. During calculating the steady-state parameters, the Newton-Raphson method is adopted by setting F(x)=Qₜᵢ−3Iₜᵢ²·ω·L_{apf}−Qₜ₁ᵢ. Where, i indicates a N-th power point, x=U_{L}. An initial value and an iteration step size are set, and if F(x1)=0, the iteration ends. Where, i indicates a N-th power point, Qₜ indicates the reactive power output of the SVG, Iₜ indicates a current of the SVG branch, L_{apf} indicates the inductance of the connecting reactor, and U_{L} indicates a voltage at a grid connection point of the SVG.

When the above calculation process for the j-th power point under the i-th operating condition is completed, the operating characteristics of the next power point are calculated. When the converter parameters (such as the ideal control voltage and the tap-changer position of the converter transformer) at all power points are completed, the (i+1)-th power is calculated. When all results are calculated, the calculation results are saved and the operation is exited.

In operation S30: whether calculation results of the main circuit parameters are within a preset range is determined. In case that the calculation results of the main circuit parameters are within the preset range, the calculation results are outputted. In case that the calculation results of the main circuit parameters are not within the preset range, the parameters are modified and the previous operations are re-performed until the calculation results of all of the parameters are within the preset range.

The method for calculating the main circuit parameters of the SLCC is provided in the present embodiment. The method is used to guide the integrated design, system operation and control setting of an actual direct-current transmission project, and especially to provide steady-state operating parameters for the design of converter transformers and alternating-current/direct-current filters in direct-current transmission systems under the background of large-scale renewable energy integration in the future.

### Second Embodiment

Based on the same inventive concept, this embodiment provides a further explanation for the solution in the First Embodiment through a specific instance. In this embodiment, the design of a Statcom and Line Commutated Converter based High Voltage Direct Current (SLCC-HVDC) commutation technology is described by using a domestic ±800 kV project as an example. Herein, the rated voltage of the system is 800 kV, the monopole transmission power is 4000 MW, the rated firing angle is 15° and the rated extinction angle is 17°, the firing angle ranges from [12.5°,17.5°], a minimum firing angle is 5°, and the minimum extinction angle is 12°. The direct-current rated resistance R=9.65Ω. In this paper, the main circuit parameters at the transmitting terminal and the receiving terminal of the project will be calculated.

The zero reactive power exchange in the alternating-current system is selected as the control target for the SVG at the transmitting terminal and the receiving terminal. At this time, the main circuit parameters are calculated when the power of each converter station is synchronously increased from 0.1 pu to 1.2 pu under a bipolar full-voltage operating mode, a monopole earth operation condition and a monopole metal operation condition. The calculation results of the direct-current power, the direct-current voltage, the direct-current current, the no-load direct-current voltage, the firing angle/extinction angle, the commutating angle, the active power consumed by the converter and the tap-changer position of the converter transformer at each converter station are shown in Table 1 to Table 3 below.

TABLE 1
Operating characteristics of the main circuit under the bipolar full-voltage

| Power | Current | U_{dR} | U_{di0R} | U_{di0I} | U_{di02R} | U_{di02I} | P_{dR} | α | γ | | |
|---|---|---|---|---|---|---|---|---|---|---|---|
| (p.u.) | (kA) | (kV) | (kV) | (kV) | (kV) | (kV) | (MW) | (°) | (°) | TCr | TCI |
| 0.1 | 0.50 | 800 | 207.72 | 207.85 | 208.29 | 208.42 | 800 | 15 | 17 | 0 | −4 |
| 0.2 | 1.00 | 800 | 208.03 | 206.87 | 209.21 | 208.01 | 1600 | 15 | 17 | 0 | −4 |
| 0.3 | 1.50 | 800 | 208.23 | 205.81 | 210.14 | 207.61 | 2400 | 15 | 17 | −1 | −4 |
| 0.4 | 2.00 | 800 | 209.33 | 204.68 | 211.06 | 207.20 | 3200 | 15 | 17 | −1 | −3 |
| 0.5 | 2.50 | 800 | 208.31 | 203.47 | 211.99 | 206.80 | 4000 | 15 | 17 | −1 | −3 |
| 0.6 | 3.00 | 800 | 208.21 | 202.19 | 212.91 | 206.39 | 4800 | 15 | 17 | −1 | −2 |
| 0.7 | 3.50 | 800 | 208.00 | 200.83 | 213.84 | 205.98 | 5600 | 15 | 17 | 0 | −2 |
| 0.8 | 4.00 | 800 | 207.70 | 199.40 | 214.76 | 205.58 | 6400 | 15 | 17 | 0 | −1 |
| 0.9 | 4.50 | 800 | 207.29 | 197.89 | 215.68 | 205.17 | 7200 | 15 | 17 | 0 | −1 |
| 1 | 5.00 | 800 | 206.76 | 196.29 | 216.61 | 204.77 | 8000 | 15 | 17 | 0 | 0 |
| 1.1 | 5.53 | 796.3 | 205.10 | 193.52 | 216.61 | 203.37 | 8800 | 15 | 17 | 1 | 1 |
| 1.2 | 6.06 | 792.5 | 203.29 | 190.62 | 216.61 | 201.95 | 9600 | 15 | 17 | 1 | 2 |

TABLE 2
Operation characteristics of the main circuit under the monopole earth

| Power | Current | U_{dR} | U_{di01R} | U_{di01I} | U_{di02R} | U_{di02I} | P_{dR} | α | γ | | |
|---|---|---|---|---|---|---|---|---|---|---|---|
| (p.u.) | (kA) | (kV) | (kV) | (kV) | (kV) | (kV) | (MW) | (°) | (°) | TCr | TCI |
| 0.1 | 0.50 | 800 | 207.72 | 207.32 | 208.29 | 207.89 | 400 | 15 | 17 | 0 | −4 |
| 0.2 | 1.00 | 800 | 208.03 | 205.81 | 209.21 | 206.96 | 800 | 15 | 17 | 0 | −4 |
| 0.3 | 1.50 | 800 | 208.23 | 204.23 | 210.14 | 206.02 | 1200 | 15 | 17 | −1 | −3 |
| 0.4 | 2.00 | 800 | 209.33 | 202.56 | 211.06 | 205.09 | 1600 | 15 | 17 | −1 | −2 |
| 0.5 | 2.50 | 800 | 208.31 | 200.82 | 211.99 | 204.16 | 2000 | 15 | 17 | −1 | −2 |
| 0.6 | 3.00 | 800 | 208.21 | 199.00 | 212.91 | 203.22 | 2400 | 15 | 17 | −1 | −1 |
| 0.7 | 3.50 | 800 | 208.00 | 197.10 | 213.84 | 202.29 | 2800 | 15 | 17 | 0 | 0 |
| 0.8 | 4.00 | 800 | 207.70 | 195.13 | 214.76 | 201.35 | 3200 | 15 | 17 | 0 | 0 |
| 0.9 | 4.50 | 800 | 207.29 | 193.06 | 215.68 | 200.42 | 3600 | 15 | 17 | 0 | 1 |
| 1 | 5.00 | 800 | 206.76 | 190.91 | 216.61 | 199.49 | 4000 | 15 | 17 | 0 | 2 |
| 1.1 | 5.53 | 796.3 | 205.10 | 187.54 | 216.61 | 197.53 | 4400 | 15 | 17 | 1 | 4 |
| 1.2 | 6.06 | 792.5 | 203.29 | 184.03 | 216.61 | 195.55 | 4800 | 15 | 17 | 1 | 5 |

TABLE 3
Operating characteristics of the main circuit under the monopole metal

| Power | Current | U_{dR} | U_{di01R} | U_{di01I} | U_{di02R} | U_{di02I} | P_{dR} | α | γ | | |
|---|---|---|---|---|---|---|---|---|---|---|---|
| (p.u.) | (kA) | (kV) | (kV) | (kV) | (kV) | (kV) | (MW) | (°) | (°) | TCr | TCI |
| 0.1 | 0.50 | 800 | 207.72 | 206.59 | 208.29 | 207.16 | 400 | 15 | 17 | 0 | −4 |
| 0.2 | 1.00 | 800 | 208.03 | 204.34 | 209.21 | 205.49 | 800 | 15 | 17 | 0 | −3 |
| 0.3 | 1.50 | 800 | 208.23 | 202.02 | 210.14 | 203.82 | 1200 | 15 | 17 | −1 | −2 |
| 0.4 | 2.00 | 800 | 209.33 | 199.62 | 211.06 | 202.16 | 1600 | 15 | 17 | −1 | −1 |
| 0.5 | 2.50 | 800 | 208.31 | 197.13 | 211.99 | 200.49 | 2000 | 15 | 17 | −1 | 0 |
| 0.6 | 3.00 | 800 | 208.21 | 194.57 | 212.91 | 198.82 | 2400 | 15 | 17 | −1 | 1 |
| 0.7 | 3.50 | 800 | 208.00 | 191.92 | 213.84 | 197.15 | 2800 | 15 | 17 | 0 | 2 |
| 0.8 | 4.00 | 800 | 207.70 | 189.19 | 214.76 | 195.49 | 3200 | 15 | 17 | 0 | 3 |
| 0.9 | 4.50 | 800 | 207.29 | 186.36 | 215.68 | 193.82 | 3600 | 15 | 17 | 0 | 4 |
| 1 | 5.00 | 800 | 206.76 | 183.43 | 216.61 | 192.15 | 4000 | 15 | 17 | 0 | 6 |
| 1.1 | 5.53 | 796.3 | 205.10 | 179.22 | 216.61 | 189.42 | 4400 | 15 | 17 | 1 | 8 |
| 1.2 | 6.06 | 792.5 | 203.29 | 174.85 | 216.61 | 186.66 | 4800 | 15 | 17 | 1 | 10 |

The zero reactive power exchange in the alternating-current system is selected as the control target for the SVG at the transmitting terminal and the receiving terminal, and the reduced-voltage coefficient k=0.8 is set. At this time, the main circuit parameters are calculated when the power of each converter station is synchronously increased from 0.1 pu to 1.2 pu under a bipolar full-voltage operating mode, a monopole earth operation condition and a monopole metal operation condition. The calculation results of the direct-current power, the direct-current voltage, the direct-current current, the no-load direct-current voltage, the firing angle/extinction angle, the commutating angle, the active power consumed by the converter and the tap-changer position of the converter transformer at each converter station are shown in Table 4 to Table 6 below.

TABLE 4
Operation characteristics of the main circuit under the bipolar earth

| Power | Current | U_{dR} | U_{di01R} | U_{di01I} | U_{di02R} | U_{di02I} | P_{dR} | α | γ | | |
|---|---|---|---|---|---|---|---|---|---|---|---|
| (p.u.) | (kA) | (kV) | (kV) | (kV) | (kV) | (kV) | (MW) | (°) | (°) | TCr | TCI |
| 0.1 | 0.625 | 640 | 166.39 | 165.78 | 167.11 | 166.49 | 800 | 15 | 17 | 19 | 15 |
| 0.2 | 1.25 | 640 | 166.66 | 164.48 | 168.27 | 165.98 | 1600 | 15 | 17 | 19 | 15 |
| 0.3 | 1.875 | 640 | 166.73 | 163.02 | 169.42 | 165.48 | 2400 | 15 | 17 | 19 | 16 |
| 0.4 | 2.5 | 640 | 165.60 | 161.42 | 170.58 | 164.97 | 3200 | 15 | 17 | 20 | 17 |
| 0.5 | 3.125 | 640 | 166.27 | 159.68 | 171.73 | 164.46 | 4000 | 15 | 17 | 19 | 18 |
| 0.6 | 3.75 | 640 | 165.75 | 157.77 | 172.89 | 163.95 | 4800 | 15 | 17 | 20 | 20 |
| 0.7 | 4.375 | 640 | 165.01 | 155.71 | 174.04 | 163.45 | 5600 | 15 | 17 | 20 | 21 |
| 0.8 | 5 | 640 | 164.05 | 153.48 | 175.20 | 162.94 | 6400 | 15 | 17 | 21 | 22 |

TABLE 5
Operation characteristics of the main circuit under the monopole earth

| Power | Current | U_{dR} | U_{di01R} | U_{di01I} | U_{di02R} | U_{di02I} | P_{dR} | α | γ | | |
|---|---|---|---|---|---|---|---|---|---|---|---|
| (p.u.) | (kA) | (kV) | (kV) | (kV) | (kV) | (kV) | (MW) | (°) | (°) | TCr | TCI |
| 0.1 | 0.625 | 640 | 166.39 | 165.12 | 167.11 | 165.83 | 400 | 15 | 17 | 19 | 15 |
| 0.2 | 1.25 | 640 | 166.66 | 163.15 | 168.27 | 164.66 | 800 | 15 | 17 | 19 | 16 |
| 0.3 | 1.875 | 640 | 166.73 | 161.04 | 169.42 | 163.49 | 1200 | 15 | 17 | 19 | 18 |
| 0.4 | 2.5 | 640 | 165.60 | 158.76 | 170.58 | 162.33 | 1600 | 15 | 17 | 20 | 19 |
| 0.5 | 3.125 | 640 | 166.27 | 156.34 | 171.73 | 161.16 | 2000 | 15 | 17 | 19 | 20 |
| 0.6 | 3.75 | 640 | 165.75 | 153.75 | 172.89 | 147.17 | 2400 | 15 | 17 | 20 | 22 |
| 0.7 | 4.375 | 640 | 165.01 | 150.99 | 174.04 | 158.83 | 2800 | 15 | 17 | 20 | 24 |
| 0.8 | 5 | 640 | 164.05 | 149.58 | 175.20 | 159.46 | 3200 | 15 | 19 | 21 | 25 |

TABLE 6
Operating characteristics of the main circuit under the monopole metal

| Power | Current | U_{dR} | U_{di01R} | U_{di01I} | U_{di02R} | U_{di02I} | P_{dR} | α | γ | | |
|---|---|---|---|---|---|---|---|---|---|---|---|
| (p.u.) | (kA) | (kV) | (kV) | (kV) | (kV) | (kV) | (MW) | (°) | (°) | TCr | TCI |
| 0.1 | 0.625 | 640 | 166.39 | 164.21 | 167.11 | 164.91 | 400 | 15 | 17 | 19 | 16 |
| 0.2 | 1.25 | 640 | 166.66 | 161.32 | 168.27 | 162.83 | 800 | 15 | 17 | 19 | 17 |
| 0.3 | 1.875 | 640 | 166.73 | 158.27 | 169.42 | 160.75 | 1200 | 15 | 17 | 19 | 19 |
| 0.4 | 2.5 | 640 | 165.60 | 155.07 | 170.58 | 158.66 | 1600 | 15 | 17 | 20 | 21 |
| 0.5 | 3.125 | 640 | 166.27 | 151.70 | 171.73 | 156.58 | 2000 | 15 | 17 | 19 | 24 |
| 0.6 | 3.75 | 640 | 165.75 | 149.60 | 172.89 | 156.26 | 2400 | 15 | 19.0 | 20 | 25 |
| 0.7 | 4.375 | 640 | 165.01 | 149.60 | 174.04 | 158.34 | 2800 | 15 | 23.0 | 20 | 25 |
| 0.8 | 5 | 640 | 164.05 | 149.60 | 175.20 | 160.63 | 3200 | 15 | 26.5 | 21 | 25 |

### Third Embodiment

Based on the same inventive concept, the present embodiment provides a system for calculating main circuit parameters of an SLCC, and the system includes a calculation section for a no-load rated direct-current voltage, a calculation section for the main circuit parameters and an output section.

The calculation section for a no-load rated direct-current voltage is configured to calculate the ideal no-load rated direct-current voltage through a Newton-Raphson iteration method based on an equivalent circuit model and a simplified equivalent circuit model.

The calculation section for the main circuit parameters is configured to calculate a main circuit parameter in the equivalent circuit model and a main circuit parameter in the simplified equivalent circuit model based on the ideal no-load rated direct-current voltage in combination with a reactive power control target for an alternating-current system and an angle control target for a direct-current system.

The output section is configured to determine whether calculation results of the main circuit parameter are within a preset range. In case that the calculation results of the main circuit parameters are within the preset range, the calculation results are outputted. In case that the calculation results of the main circuit parameters are not within the preset range, the parameters are modified and the previous operations are re-performed until the calculation results of all of the parameters are within the preset range.

### Fourth Embodiment

Based on the same inventive concept, the present embodiment provides a computer-readable storage medium having stored thereon computer programs that, when executed by a processor, implement the method for calculating the main circuit parameters of the SLCC of any one of the described above.

It will be appreciated by those of skilled in the art that embodiments of the disclosure may be provided as a method, a system, or a computer program product. Accordingly, the disclosure can be embodied in the form of an entirely hardware embodiment, an entirely software embodiment, or an embodiment combining software aspects and hardware aspects. Furthermore, the disclosure can be embodied in the form of a computer program product implemented on one or more computer-usable storage media (including but not limited to magnetic disk storage, CD-ROM, optical memory, etc.) in which computer-usable program codes are contained.

The disclosure is described with reference to flowcharts and/or block diagrams of a method, an apparatus (a system), and a computer program product according to embodiments of the disclosure. It should be understood that each flow in the flowcharts and/or each block in the block diagrams, as well as combinations of flows in the flowcharts and/or blocks in the block diagrams, may be implemented by computer program instructions. These computer program instructions may be provided to a general purpose computer, a special purpose computer, an embedded processor, or a processor of other programmable data processing apparatus to generate a machine, such that the instructions executed by the computer or the processor of other programmable data processing apparatus generate an apparatus for implementing the functions specified in one or more flows in the flowcharts or one or more blocks in the block diagrams.

These computer program instructions may also be stored in a computer-readable memory capable of directing a computer or other programmable data processing apparatus to operate in a particular manner, such that the instructions stored in the computer-readable memory generate an article of manufacture containing a instruction device that implement the functions specified in one or more flows in the flowcharts or one or more blocks in the block diagrams.

These computer program instructions may also be loaded onto a computer or other programmable data processing apparatus, such that a series of operational steps are executed on the computer or other programmable apparatus to generate computer-implemented processes, and thus, the instructions executed on the computer or other programmable apparatus provide operations for implementing the functions specified in one or more flows in the flowcharts or one or more blocks in the block diagrams.

Finally, it should be noted that the above embodiments are merely used to illustrate the technical solutions of the disclosure and not to limit the implementations. Although the disclosure has been described in detail with reference to the above embodiments, it should be understood by those of ordinary skilled in the art that modifications or equivalent substitutions can still be made to specific implementations of the disclosure, and any modification or equivalent substitution without departing from the spirit and scope of the disclosure shall be covered within the scope of protection of the claims of the disclosure. The above content is merely the specific implementations of the disclosure; however, the scope of protection of the disclosure is not limited thereto. Any change or substitution apparent to the skilled person familiar with the technical field within the technical scope disclosed by the disclosure shall be covered within the scope of protection of the disclosure. Therefore, the scope of protection of the disclosure shall be defined by the appended claims.

### INDUSTRIAL APPLICABILITY

In the embodiments of the disclosure, a method and system for calculating main circuit parameters of an SLCC, and a readable medium are provided. The method includes the following operations. An ideal no-load rated direct-current voltage is calculated through a Newton-Raphson iteration method based on an equivalent circuit model and a simplified equivalent circuit model. A main circuit parameter in the equivalent circuit model and a main circuit parameter in the simplified equivalent circuit model are calculated based on the ideal no-load rated direct-current voltage in combination with a reactive power control target for an alternating-current system and an angle control target for a direct-current system. Whether calculation results of the main circuit parameters are within a preset range is determined. In case that the calculation results of the main circuit parameters are within the preset range, the calculation results are outputted. In case that the calculation results of the main circuit parameters are not within the preset range, the parameters are modified and the previous operations are re-performed until the calculation results of all of the parameters are within the preset range. The embodiments of the disclosure can quickly and accurately calculate parameters such as the direct-current voltage and the direct-current current, the active power and the reactive power, the tap-changer position and the reactive power output of the SVG for each of the power points at the transmitting terminal and the receiving terminal, thereby providing reliable data for the selection of key equipment in the direct-current system.

1. A method for calculating main circuit parameters of a Statcom and Line Commutation Converter (SLCC), comprising:
calculating an ideal no-load rated direct-current voltage through a Newton-Raphson iteration method based on an equivalent circuit model and a simplified equivalent circuit model;
calculating a main circuit parameter in the equivalent circuit model and a main circuit parameter in the simplified equivalent circuit model based on the ideal no-load rated direct-current voltage in combination with a reactive power control target for an alternating-current system and an angle control target for a direct-current system; and
determining whether calculation results of the main circuit parameters are within a preset range; in case that the calculation results of the main circuit parameters are within the preset range, outputting the calculation results; and in case that the calculation results of the main circuit parameters are not within the preset range, modifying the main circuit parameters and re-performing the previous operations until the calculation results of all of the main circuit parameters are within the preset range.

2. The method for calculating the main circuit parameters of the SLCC of claim 1, wherein the equivalent circuit model comprises a main circuit and a Static Var Compensator (SVG) branch, the main circuit comprises a first alternating-current signal source and an equivalent impedance of a converter transformer, the first alternating-current signal source is connected in series with the equivalent impedance of the converter transformer, and an output terminal of the equivalent impedance of the converter transformer is connected to a converter valve of a Line commutated converter (LCC); and the SVG branch comprises a second alternating-current signal source and an inductance of a connecting reactor, the second alternating-current signal source is connected in series with the inductance of the connecting reactor, and an output terminal of the inductance of the connecting reactor is connected to the main circuit.

3. The method for calculating the main circuit parameters of the SLCC of claim 2, wherein the simplified equivalent circuit model comprises a third alternating-current signal source and a synthetic equivalent impedance of a combined impedance of the converter transformer and the SVG, the third alternating-current signal source is connected in series with the synthetic equivalent impedance of the combined impedance of the converter transformer and the SVG, and an output terminal of the synthetic equivalent impedance of the combined impedance of the converter transformer and the SVG is connected to the converter valve of the LCC.

4. The method for calculating the main circuit parameters of the SLCC of claim 3, wherein calculating the ideal no-load rated direct-current voltage comprises:
calculating the main circuit parameter in the simplified equivalent circuit model based on an initial value of a voltage parameter at a grid connection point;
calculating the main circuit parameter in the equivalent circuit model based on the initial value of the voltage parameter at the grid connection point;
calculating a parameter of the SVG branch of the equivalent circuit model based on the initial value of the voltage parameter at the grid connection point; and
iteratively solving the ideal no-load rated direct-current voltage based on the main circuit parameter in the simplified equivalent circuit model, the main circuit parameter in the equivalent circuit model and the parameter of the SVG branch of the equivalent circuit model.

5. The method for calculating the main circuit parameters of the SLCC of claim 4, wherein the main circuit parameter in the simplified equivalent circuit model comprises: a commutating angle, reactive power consumption, and a transmission current; the main circuit parameter in the equivalent circuit model comprises: reactive power consumption of the converter transformer, a grid-side current and a power factor; and the parameter of the SVG branch of the equivalent circuit model comprises: a reactive power output of the SVG, a reactive power consumption of the connecting reactor, a reactive power consumption when disconnected and a voltage of a voltage source in the SVG.

6. The method for calculating the main circuit parameters of the SLCC of claim 1, wherein calculating the main circuit parameter in the equivalent circuit model and the main circuit parameter in the simplified equivalent circuit model comprises: setting a power step size under a plurality of operating conditions and a plurality of powers and an actual reactive power exchange control value for each of power points; calculating operating characteristics of the direct-current system under the plurality of operating conditions with condition constraints through the Newton-Raphson iteration method; and determining the main circuit parameter in the equivalent circuit model and the main circuit parameter in the simplified equivalent circuit model.

7. The method for calculating the main circuit parameters of the SLCC of claim 6, further comprising: under a full-voltage operating condition, setting a reactive power exchange control value for a direct-current power, and calculating a steady-state parameter for each of the power points one by one; wherein during calculating the steady-state parameter, adopting the Newton-Raphson iteration method by setting: F(x)=Qₜᵢ−3I₁₂·ω·L_{apf}−Qₜ₁ᵢ, x=U_{L}, an initial value and an iteration step size are set, and when F(x1)=0, the iteration ends; where i indicates a N-th power point, Qₜ indicates a reactive power output of a Static Var Compensator (SVG), Iₜ indicates a current of an SVG branch, L_{apf} indicates an inductance of a connecting reactor, and U_{L} indicates a voltage at a grid connection point of the SVG.

8. The method for calculating the main circuit parameters of the SLCC of claim 6, further comprising: under a reduced-voltage operating condition, setting a reduced-voltage coefficient k, setting a reactive power exchange control value of a direct-current power from 0.1 to k, and calculating a steady-state parameter for each of the power points one by one; wherein during calculating the steady-state parameters, adopting the Newton-Raphson iteration method by setting F(x)=Qₜᵢ−3Iₜᵢ²·ω·L_{apf}−Qₜ₁ᵢ, where i indicates a N-th power point, x=U_{L}, an initial value and an iteration step size are set, and when F(x1)=0, the iteration ends, where Qₜ indicates a reactive power output of Static Var Compensator (SVG), Iₜ indicates a current of an SVG branch, L_{apf} indicates an inductance of a connecting reactor, and U_{L} indicates a voltage at a grid connection point of the SVG.

9. A system for calculating main circuit parameters of a Statcom and line commutation converter (SLCC), comprising:
a processor; and
a memory configured to store an instruction executable on the processor, wherein the processor is configured to:
calculate an ideal no-load rated direct-current voltage through a Newton-Raphson iteration method based on an equivalent circuit model and a simplified equivalent circuit model;
calculate a main circuit parameter in the equivalent circuit model and a main circuit parameter in the simplified equivalent circuit model based on the ideal no-load rated direct-current voltage in combination with a reactive power control target for an alternating-current system and an angle control target for a direct-current system; and
determine whether calculation results of the main circuit parameter are within a preset range; in case that the calculation results of the main circuit parameters are within the preset range, output the calculation results; and in case that the calculation results of the main circuit parameters are not within the preset range, modify the main circuit parameters and re-perform the previous operations until the calculation results of all of the main circuit parameters are within the preset range.

10. A non-transitory computer-readable storage medium having stored thereon computer programs that when executed by a processor, implement the method for calculating the main circuit parameters of the SLCC of claim 1.

11. The system for calculating the main circuit parameters of the SLCC of claim 9, wherein the equivalent circuit model comprises a main circuit and a Static Var Compensator (SVG) branch, the main circuit comprises a first alternating-current signal source and an equivalent impedance of a converter transformer, the first alternating-current signal source is connected in series with the equivalent impedance of the converter transformer, and an output terminal of the equivalent impedance of the converter transformer is connected to a converter valve of a Line commutated converter (LCC); and the SVG branch comprises a second alternating-current signal source and an inductance of a connecting reactor, the second alternating-current signal source is connected in series with the inductance of the connecting reactor, and an output terminal of the inductance of the connecting reactor is connected to the main circuit.

12. The system for calculating the main circuit parameters of the SLCC of claim 11, wherein the simplified equivalent circuit model comprises a third alternating-current signal source and a synthetic equivalent impedance of a combined impedance of the converter transformer and the SVG, the third alternating-current signal source is connected in series with the synthetic equivalent impedance of the combined impedance of the converter transformer and the SVG, and an output terminal of the synthetic equivalent impedance of the combined impedance of the converter transformer and the SVG is connected to the converter valve of the LCC.

13. The system for calculating the main circuit parameters of the SLCC of claim 12, wherein the processor is further configured to:
calculate the main circuit parameter in the simplified equivalent circuit model based on an initial value of a voltage parameter at a grid connection point;
calculate the main circuit parameter in the equivalent circuit model based on the initial value of the voltage parameter at the grid connection point;
calculate a parameter of the SVG branch of the equivalent circuit model based on the initial value of the voltage parameter at the grid connection point; and
iteratively solve the ideal no-load rated direct-current voltage based on the main circuit parameter in the simplified equivalent circuit model, the main circuit parameter in the equivalent circuit model and the parameter of the SVG branch of the equivalent circuit model.

14. The system for calculating the main circuit parameters of the SLCC of claim 13, wherein the main circuit parameter in the simplified equivalent circuit model comprises: a commutating angle, reactive power consumption, and a transmission current; the main circuit parameter in the equivalent circuit model comprises: reactive power consumption of the converter transformer, a grid-side current and a power factor; and the parameter of a SVG branch of the equivalent circuit model comprises: a reactive power output of the SVG, a reactive power consumption of the connecting reactor, a reactive power consumption when disconnected and a voltage of a voltage source in the SVG.

15. The system for calculating the main circuit parameters of the SLCC of claim 9, wherein the processor is further configured to: set a power step size under a plurality of operating conditions and a plurality of powers and an actual reactive power exchange control value for each of power points; calculate operating characteristics of the direct-current system under the plurality of operating conditions with condition constraints through the Newton-Raphson iteration method; and determine the main circuit parameter in the equivalent circuit model and the main circuit parameter in the simplified equivalent circuit model.

16. The system for calculating the main circuit parameters of the SLCC of claim 15, wherein the processor is further configured to: under a full-voltage operating condition, set a reactive power exchange control value for a direct-current power, and calculate a steady-state parameter for each of the power points one by one; wherein during calculating the steady-state parameter, adopt the Newton-Raphson iteration method by setting: F(x)=Qₜᵢ−3Iₜᵢ²·ω·L_{apf}−Qₜ₁ᵢ, x=U_{L}, an initial value and an iteration step size are set, and when F(x1)=0, the iteration ends; where i indicates a N-th power point, Qₜ indicates a reactive power output of a Static Var Compensator (SVG), Iₜ indicates a current of an SVG branch, L_{apf} indicates an inductance of a connecting reactor, and U_{L} indicates a voltage at a grid connection point of the SVG.

17. The system for calculating the main circuit parameters of the SLCC of claim 15, wherein the processor is further configured to: under a reduced-voltage operating condition, set a reduced-voltage coefficient k, set a reactive power exchange control value of a direct-current power from 0.1 to k, and calculate a steady-state parameter for each of the power points one by one; wherein during calculating the steady-state parameters, adopt the Newton-Raphson iteration method by setting F(x)=Qₜᵢ−3Iₜᵢ²·ω·L_{apf}−Qₜ₁ᵢ, where i indicates a N-th power point, x=U_{L}, an initial value and an iteration step size are set, and when F(x1)=0, the iteration ends, where Qₜ indicates a reactive power output of a Static Var Compensator (SVG), Iₜ indicates a current of an SVG branch, L_{apf} indicates an inductance of a connecting reactor, and U_{L} indicates a voltage at a grid connection point of the SVG.
